(19) United States
(12) Patent Application Publication
(10) Pub. No.: US 2007/0269973 A1
(43) Pub. Date: Nov. 22, 2007

(54) Method of providing solder bumps using reflow in a forming gas atmosphere

(76) Inventors: Ravi K. Nalla, Chandler, AZ (US); Mengzhi Pang, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/437,029

(22) Filed: May 19, 2006

(51) Int. Cl. H01L 21/44

(52) U.S. Cl. 438/612

(57) ABSTRACT

A method of providing electrically conductive bumps on electrode pads of a microelectronic substrate. The method includes: providing a microelectronic substrate including electrode pads thereon; disposing a mask onto the substrate such that openings defined in the mask are placed in registration with the electrode pads; providing solder portions onto respective ones of the electrode pads through the mask; reflowing the solder portions in a forming gas atmosphere to form solder bumps on respective ones of the electrode pads; and removing the mask after reflowing.

### FIELD

Embodiments of the present invention relate generally to solder bump forming methods and solder bump forming apparatus for forming solder bumps on electrode pads.

### BACKGROUND

There are a number of solder bump forming methods according to the prior art. There are plating methods in which metal is deposited on electrode pads of a microelectronic device through plating to form bumps. In another method typically referred to as a stencil printing method, solder paste, typically including flux, is printed on electrode pads of a microelectronic device through a patterned stencil, and then, after stencil removal, the device is heated to melt the solder therein to form bumps. According to an attachment mounting method, solder balls are sucked into a jig by vacuum suction, and the solder balls then mounted onto flux-coated electrode pads of a substrate. The solder balls are then heated and melted to form bumps.

As electronic products are being scaled, bump pitch and bump diameter are being decreased to ultra-fine pitch dimensions, which would include, for example, a 140 micron minimum pitch and a solder resist opening measuring about 70 microns. However, most bumping technologies have proven to have limitations when being used to yield bumps at ultra-fine pitches. For example, in the case of stencil mask printing as described above currently used for fine pitch C4 substrate solder bumping of high density interconnect packages, attempts at printing at ultra-fine pitches, that is, pitches below about 150 microns, have led to poor yield, including issues of mask lift-off and missing and/or low volume bumps.

One method for addressing the need for a technique that take into account ultra-fine pitches involves a micro-ball placement (MBP) technique developed by Hitachi Metals, Ltd. This method is described with respect to prior art FIGS. 1-3.

According to Hitachi's micro-ball placement technique (MPT) as shown in FIG. 1, a substrate 100 is provided including electrode pads 102 thereon. A metal mask 104 is held onto the substrate 100, the mask 104 having holes 106 defined therein which are placed in registration with the electrode pads of the substrate. Thereafter, a printing flux 108 is pressed onto the electrode pads 102 with a squeegee 110. The printing flux 108 adheres to the surface of the substrate 100 at the location of the holes 106 in the mask 104. Referring to FIG. 2, after flux printing, the metal mask 104 is removed, and a metal ball alignment mask/plate 112 defining holes 114 therein is placed onto the substrate such that the holes 114 are in registration with the electrode pads 102. Solder balls 115, lead-free or otherwise, are then dispensed onto the ball alignment plate 112. A squeegee brush 116 is then used to disperse the balls 115 while at the same time pressing them into the mask holes 114. After placement of balls 115, the plate 112 is removed to release the balls from holes 114. The flux serves to remove any residual oxide on the solder and pads. In addition, the viscosity of the flux causes the balls 115 to adhere to the surface of the substrate 100, keeping the balls stabilized during and after positioning. Thereafter, referring to FIG. 3, the substrate is placed in a solder reflow oven, at which point the application of heat fixes the solder balls in place, vaporizes the flux and converts the solder balls to solder bumps 116. Hitachi claims the MBP method is capable of mounting balls 80 microns in diameter at a pitch of 150 microns.

Disadvantageously, the MBP method requires that the flux chemistry and quantity be optimized for each solder ball alloy composition in order to avoid voiding of the solder bumps formed. Practically speaking, the MBP method can still result in substantial solder bump voiding.

The prior art fails to provide a reliable method of providing solder bumps on electrode pads of microelectronic devices.

### BRIEF DESCRIPTION OF THE DRAWINGS

FIG. 1 is a schematic, cross sectional view of a substrate being provided with solder paste according to the prior art;

FIG. 2 is a schematic, cross sectional view showing the substrate of FIG. 1 as being provided with solder balls according to the prior art;

FIG. 3 is a schematic, cross sectional view showing the substrate of FIGS. 1 and 2 as having been provided with solder bumps according to the prior art;

FIG. 4 is a schematic, cross sectional view showing a substrate including a solder resist thereon;

FIG. 5 is a schematic, cross sectional view showing the substrate of FIG. 4 as being provided with solder balls according to one embodiment;

FIG. 6 is a schematic, cross sectional view showing the substrate of FIG. 4 as being provided with solder balls according to another embodiment;

FIG. 7 is a schematic, cross sectional view showing the substrate of FIG. 4 as having been provided with solder balls according to an embodiment;

FIG. 8a is a schematic, cross sectional view showing the electrode pads of the substrate of FIG. 4 as being cleaned with a no-clean flux according to one embodiment;

FIG. 8b is a schematic, cross sectional view showing the electrode pads of the substrate of FIG. 4 as being cleaned with a plasma according to another embodiment;

FIG. 9 is a schematic, cross sectional view showing the substrate of FIG. 4 including solder balls thereon as undergoing reflow according to an embodiment; and

FIG. 10 is a schematic view of a system including a substrate having been provided with solder bumps according to one embodiment.

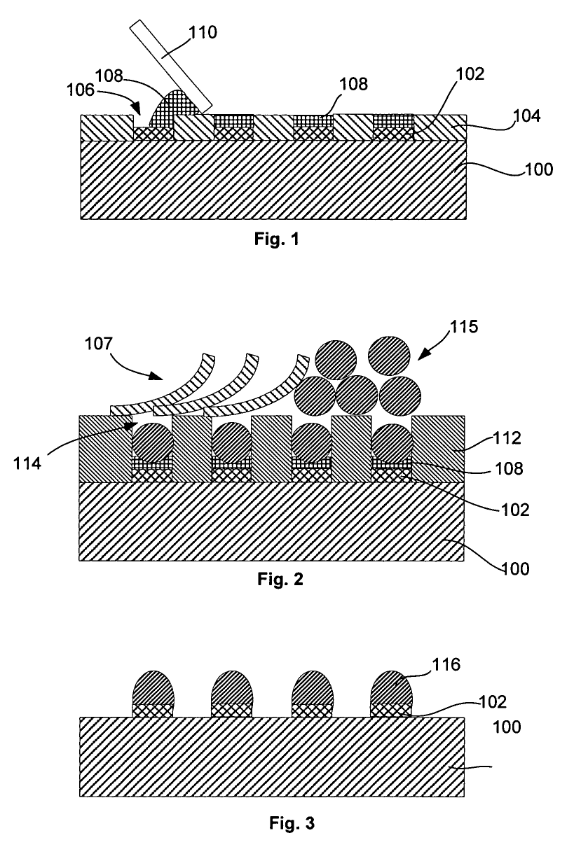

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a method of providing solder bumps onto a microelectronic substrate is disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

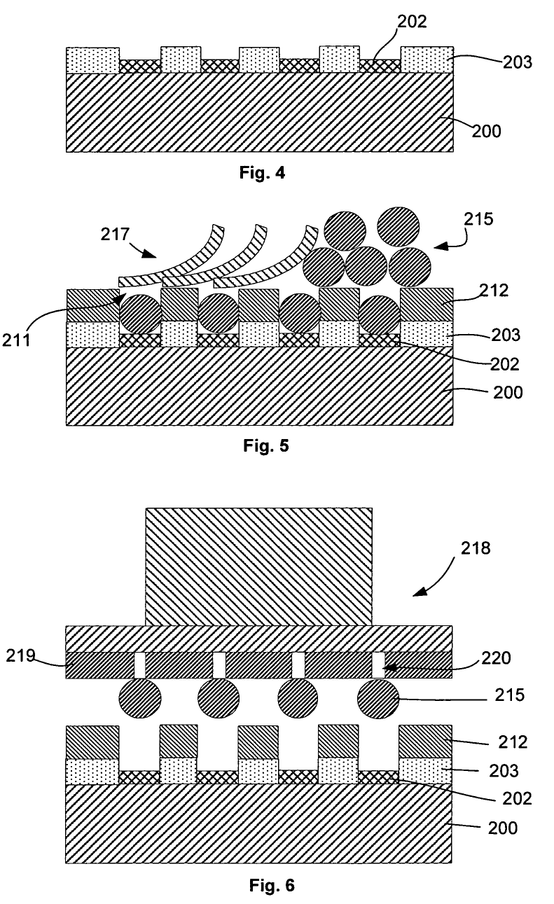

In one embodiment, a method of placing solder bumps on electrode pads of a microelectronic substrate is disclosed. By “electrode pads,” what is meant in the context of the instant description are bumping sites on a microelectronic device, such as under-bump metallization layers or “surface finish” layers, which allow the device to be electrically connected to other devices. Aspects of this and other embodiments will be discussed herein with respect to FIGS. 4-9, below. The figures, however, should not be taken to be limiting, as they are intended for the purpose of explanation and understanding.

Referring first to FIG. 4 by way of example, a method embodiment comprises providing a microelectronic substrate including electrode pads thereon. By “microelectronic substrate,” what is meant in the context of the instant description is a substrate onto which microelectronic conductive patterns have been provided. The substrate may include either the substrate of a completed microelectronic device, or a substrate adapted to be further processed to form a microelectronic device, or a substrate, such as a printed wiring board, including conductive patterns adapted to provide interconnection between microelectronic components. For example the substrate can be an organic build-up substrate, a ceramic substrate, or a semiconductor substrate, such as a silicon substrate of a microelectronic die. As seen in FIG. 4, a method embodiment comprises providing a microelectronic substrate 200 including electrode pads 202 thereon. The electrode pads 202 may include any well known type of surface finish on the substrate, such as, for example, under bump metallization including layers of gold and nickel as would be within the knowledge of a person skilled in the art. According to one embodiment, the substrate may include a solder resist layer 203 thereon. The solder resist layer 203 (also called a “solder mask” or “stop-off”) is an insulating layer that is patterned with holes according to a pattern of the electrode pads. The solder resist may include a heat-resisting coating material applied to specific areas on the surface of a substrate, and is provided mainly as a protective film for the conductive patterns of the substrate. According to an embodiment, solder resist layer 203 may include a mixture of an epoxy resin and an acrylic resin, and may be coated onto the substrate in a well known manner. It is noted that embodiments are not limited to the use of a substrate including a solder resist thereon, and include within their scope a processing of a substrate free of a solder resist, such as, for example, substrate 100 of FIG. 1.

Referring next to FIGS. 5 and 6 by way of example, embodiments contemplate disposing a mask 212 onto the substrate 200 such that openings 211 defined in the mask are placed in registration with the electrode pads 202. As seen in FIGS. 5 and 6, a mask, such as mask 212, according to embodiments may include a pattern of openings 211 therein, the pattern corresponding to a pattern of electrode pads 202 of the substrate 200. The mask may include any suitable material as would be within the knowledge of a skilled person, such as, for example, a metal mask or a mask made of an organic material. The mask may be made of a material that is not wettable by the solder, and may comprise, for example, nickel or a nickel-chrome mixture. Additionally, the mask may be placed onto the substrate in any well known manner. After placement of the mask 212 onto substrate 200 such that openings 211 register with electrode pads 202, solder portions may be provided onto respective ones of the electrode pads 202 as will be explained hereinafter with respect to FIGS. 5 and 6. According to a preferred embodiment, the solder portions may comprise solder balls 215, as shown for example in FIGS. 5 and 6. It is noted however that embodiments are not limited to solder portions comprising solder balls, but include within their scope portions of solder having any form, such as, for example, solder paste applied using well known methods such as stencil printing, with or without the use of flux. Referring back to FIG. 5, the solder balls 215 may be provided into openings 211 of mask 212 with a squeegee brush 217 or ball transfer brush, such as the squeegee brush designed by Hitachi Metals, Ltd. as part of its Micro-ball Mounter described in the Background section above. The squeegee brush 217 may thus be used to disperse the balls 215 while at the same time pressing them into the openings 211.

According to another embodiment as shown by way of example in FIG. 6, the solder portions may, similar to FIG. 5, include solder balls 215, and the solder balls may be provided into the openings 211 using, in a well known manner, a vacuum arrangement plate 219 mounted onto a bonding head 218 as shown. According to this embodiment, the solder balls 215 are sucked on through-holes 220 of arrangement plate 219 by reducing the pressure on the other side of the plate. Through holes 220 may be positioned, as shown in FIG. 6, at a position corresponding to that of electrode pads 202, and the balls 215 in this way may be transferred onto the electrode pads 202 by the plate 219 through openings 211 of mask 212.

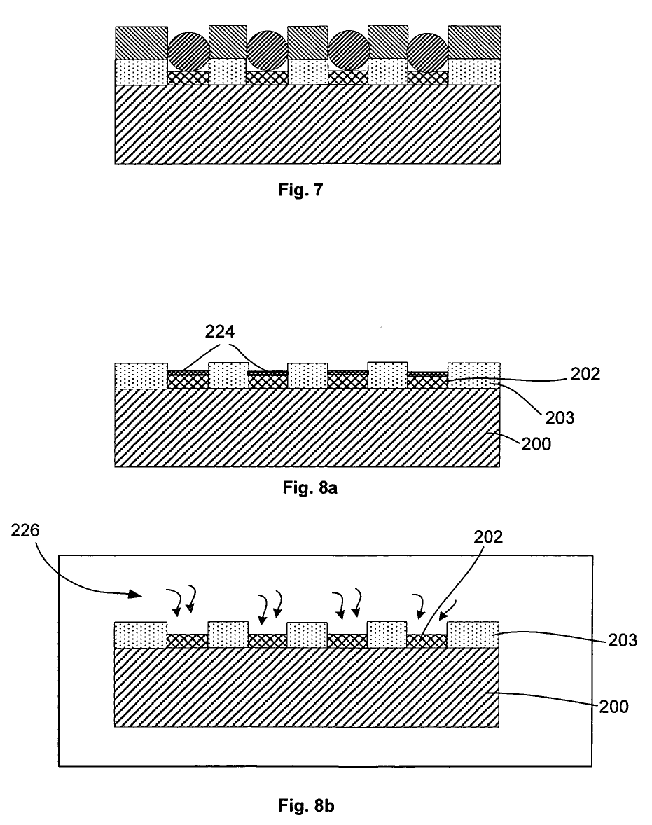

A placement of the solder portions, such as solder balls 215, onto electrode pads 202, for example according to either of the embodiments of FIG. 5 or FIG. 6, results in the formation of intermediate structure 222 as shown in FIG. 7. It is noted that embodiments are not limited to a placement of solder portions onto the substrate using either a squeegee or a vacuum plate, but include within their scope any well known manner of placing the solder portions, such as solder balls, including, for example, using electrostatic means for placing the solder balls onto the substrate. Optionally, in the embodiments of FIGS. 5 and 6, after use of the squeegee 217 or arrangement plate 219 on the solder balls 215, the substrate may be vibrated in a well known manner in order to improve a filling of the openings 211 by the solder balls 215. Additionally, optionally, a method embodiment comprises removing oxidation from the electrode pads before mounting the solder portions by using either a no-clean flux 224 as shown in FIG. 8a, or a plasma gas 226 as shown in FIG. 8b, in a well known manner. After oxidation removal, the solder portions may be placed onto the electrode pads according to embodiments, for example in the manner discussed above with respect to either of FIG. 5 or FIG. 6.

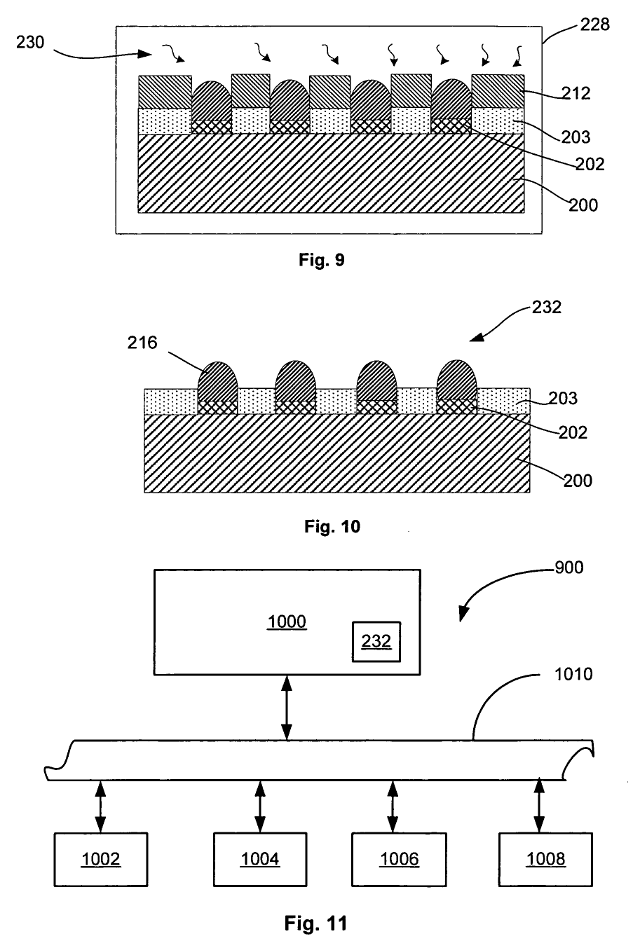

Referring next to FIG. 9 by way of example, embodiments include reflowing the solder portions in a forming gas atmosphere to form solder bumps on respective ones of the electrode pads. Thus, as seen in FIG. 9, the intermediate structure 222 of FIG. 8 may be placed in a reflow oven 228 in a forming gas atmosphere 230 as shown. The reflow may take place at reflow temperatures suitable for the intermediate structure 222 and for the solder balls 215, as would be recognizable to one skilled in the art. The forming gas atmosphere 230 may include, according to embodiments, a gas atmosphere including between about 3% and about 15% hydrogen, and the rest nitrogen. The forming gas may include impurities, such as, for example, oxygen at no more than 200 ppm. The forming gas atmosphere, according to a preferred embodiment, comprises about 95% nitrogen and about 5% hydrogen. Using about 5% hydrogen and about 95% nitrogen in the forming gas atmosphere according to a preferred embodiment is typically enough to allow a removal of oxidation for most solder ball compositions. According to an embodiment, reflow may take place at temperatures above about 250 degrees Centigrade. The 250 degrees Centigrade minimum reflow temperature would for example apply to solder balls comprising a SnAg or a SnAgCu alloy. The SnAg may comprise less than about 4% by weight Ag, while the SnAgCu may comprise less than about 1% by weight Cu and less than about 4% by weight Ag. Use of the forming gas atmosphere during reflow may reduce oxides in the solder ball. Thus, an embodiment contemplates not providing any flux onto the electrode pads of the substrate prior to reflow.

Referring now to FIG. 10 by way of example, method embodiments involve removing the mask after reflowing. Thus, as seen in FIG. 10, the reflowing of the intermediate package 222 of FIG. 8 as shown in FIG. 9 results in the formation of solder bumps 216 onto electrode pads 202 of substrate 200 yielding a solder-bumped substrate 232 as shown.

Embodiments comprise within their scope the provision of mixed pitch solder bumps by allowing the use of masks presenting openings disposed at mixed pitches with respect to one another. Thus, embodiments are not limited to masks such as mask 212 of FIGS. 5 and 6 where the openings 211 are disposed at a constant pitch with respect to one another. Additionally, embodiments comprise within their scope the use of masks presenting openings of different sizes to accommodate solder balls of differing dimensions in order to provide solder bumps of differing sizes onto the electrode pads. Thus, embodiments are not limited to masks such as mask 212 of FIGS. 5 and 6 where the openings 211 have equal sizes with respect to one another. Moreover, embodiments comprise within their scope the sequential use of masks presenting openings set at different pitches and/or having openings of different sizes with respect to a previously used mask. Thus, where electrode pads set at non-constant pitches with respect to each other (the pitches for example including a first pitch and a second pitch) are to be provided with solder bumps, an embodiment contemplates using, for example, a first mask having openings at the first pitch including providing solder portions through openings of the first mask, reflowing and removing the first mask. Thereafter, a second mask may be used having openings at the second pitch including providing solder portions through openings of the second mask, reflowing and removing the second mask. An embodiment contemplates sequentially using as many masks as there are pitches of different dimensions between the electrode pads, in the manner described above. In the alternative, where solder bumps of differing pitches are to be provided, according to a preferred embodiment, the same mask may include openings having pitches corresponding to the pitches of the bumps to be provided. Where solder bumps of differing sizes are to be provided onto the electrode pads (the sizes for example including a first size and a second size), an embodiment contemplates using, for example, a first mask having openings at the first size including providing solder portions through openings of the first mask, reflowing and removing the first mask. Thereafter, a second mask may be used having openings at the second size including providing solder portions through openings of the second mask, reflowing and removing the second mask. An embodiment contemplates sequentially using as many masks as there are solder bump sizes contemplated for the substrate, in the manner described above. An embodiment further contemplates using a mask having openings of differing sizes to accommodate solder bumps of differing sizes. Embodiments further include within their scope a sequential use of masks having openings of differing sizes and also differing pitches in the manner described above. In addition, embodiments are not limited to the use of sequential masks having openings of different pitches and/or sizes. Thus, embodiments include within their scope the sequential use, as described above, for example, of a first mask having openings according to a first pattern, and of a second mask having openings according to a second pattern. According to embodiments, each mask would therefore allow the provision of a corresponding set of solder bumps onto the substrate before the mask is lifted off.

Advantageously, method embodiments allow for finer pitch solder bumping, allowing control over bump height variations owing to better volume control on solder portions than with stencil printing. Since an embodiment provides for a flux-free process, it allows improved bump voiding control of the resulting solder bumps. Additionally, advantageously, contrary to bumping methods of the prior art, method embodiments are not dependent on of the solder portions, as embodiments do not necessitate an optimization of flux chemistry and quantity based on the solder alloy composition being used. Even where a no-clean flux or plasma is used to clean the electrode pads according to one embodiment, a composition of such no-clean flux or plasma is a function of the substrate electrode pad material(s), and any effect of the same on the solder during reflow is thus negligible. Embodiments further advantageously dispense with a need to eliminate post-reflow cleaning of flux as embodiments do not necessarily require the use of flux. Embodiments allow the bumping of ultra-fine mixed-pitch C4 substrates, for example having a minimum pitch of about 140 microns and a solder resist opening of about 70 microns. Advantageously, embodiments further allow the provision of mixed pitch and/or mixed size solder bumps by allowing the use of masks presenting openings disposed at mixed pitches with respect to one another, the use of masks presenting openings of different sizes to accommodate solder balls of differing dimension, or the sequential use of masks presenting openings set at different pitches or openings of different sizes, as explained above. Additionally, embodiments advantageously avoid the problem typically associated with mask lift off of solder paste or solder balls prior to reflow occurring in the prior art by keeping the mask onto the substrate during reflow. In this way, the solder portions are advantageously kept above the electrode pads until they form solder bumps and adhere to the pads before the mask is lifted off Referring to FIG. 11, there is illustrated one of many possible systems 900 in which embodiments of the present invention may be used. In one embodiment, the electronic assembly 1000 may include a microelectronic package 234 including a solder-bumped substrate, such as substrate 232 of FIG. 10. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 11, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method of providing electrically conductive bumps on electrode pads of a microelectronic substrate;
providing a microelectronic substrate including electrode pads thereon;
disposing a mask onto the substrate such that openings defined in the mask are placed in registration with the electrode pads;
providing solder portions onto respective ones of the electrode pads through the mask;
reflowing the solder portions in a forming gas atmosphere to form solder bumps on respective ones of the electrode pads; and
removing the mask after reflowing.

2. The method of claim 1, further comprising, prior to providing the solder portions, adding a no-clean flux to the electrode pads to remove oxidation therefrom.

3. The method of claim 1, further comprising, prior to providing the solder portions, cleaning the electrode pads using a plasma gas to remove oxidation therefrom.

4. The method of claim 1, wherein the mask comprises a metal.

5. The method of claim 4, wherein the mask comprises one of nickel or a nickel-chrome mixture.

6. The method of claim 1, wherein the mask comprises an organic material.

7. The method of claim 1, wherein the mask defines openings set at differing pitches with respect to one another.

8. The method of claim 7, wherein the mask defines openings having differing sizes with respect to one another.

9. The method of claim 1, wherein:
disposing a mask comprises providing a first mask defining openings according to a first pattern corresponding to a pattern of a first set of electrode pads on the substrate;
providing solder portions comprises providing a first set of solder portions onto the first set of electrode pads through the first mask;
reflowing comprises reflowing the first set of solder portions in a forming gas atmosphere to form a first set of solder bumps; and
removing comprises removing the first mask;
the method further includes:
disposing a second mask defining openings according to a second pattern corresponding to a pattern of a second set of electrode pads on the substrate;
providing a second set of solder portions onto the second set of electrode pads through the second mask;
reflowing the second set of solder portions in a forming gas atmosphere to form a second set of solder bumps; and
removing the second mask.

10. The method of claim 9, wherein the openings of the first mask are set at a first pitch relative to one another, and the openings of the second mask are set at a second pitch relative to one another different from the first pitch.

11. The method of claim 9, wherein the openings of the first mask have a first size, and the openings of the second mask have a second size different from the first size.

12. The method of claim 1, wherein the solder portions comprise respective solder balls.

13. The method of claim 12, wherein providing solder portions onto respective ones of the electrode pads comprises placing the solder balls into respective ones of the openings using one of a vacuum head or a squeegee.

14. The method of claim 12, wherein providing solder portions onto respective ones of the electrode pads comprises vibrating the substrate.

15. The method of claim 12, wherein the forming gas atmosphere comprises about 95% nitrogen and about 5% hydrogen.

16. The method of claim 1, wherein the substrate comprises a solder resist layer thereon, the solder resist layer defining openings therein, the openings on the solder resist being disposed in registration with the electrode pads.

17. The method of claim 16, wherein the solder resist comprises a mixture of an epoxy resin and an acrylic resin.

18. The method of claim 1, wherein the method does not include providing a flux material onto the electrode pads.

19. The method of claim 1, wherein reflowing comprises reflowing at a temperature equal to or above about 250 degrees Centigrade.

20. The method of claim 1, wherein the substrate is the substrate of a microelectronic die.

21. The method of claim 1, wherein the substrate is the substrate of a printed circuit board.

22. The method of claim 1, wherein the substrate is one of an organic substrate, a silicon substrate, and a ceramic substrate.
